(19) United States
(12) Patent Application Publication
(10) Pub. No.: US 2015/0171203 A1
(43) Pub. Date: Jun. 18, 2015

(54) FIELD-EFFECT TRANSISTOR

(71) Applicants: Shinichi Handa, Osaka-shi (JP); Tetsuzo Nagahisa, Osaka-shi (JP); Shinichi Sato, Osaka-shi (JP)

(72) Inventors: Shinichi Handa, Osaka-shi (JP); Tetsuzo Nagahisa, Osaka-shi (JP); Shinichi Sato, Osaka-shi (JP)

(73) Assignee: SHARP KABUSHIKI KAISHA, Osaka-shi, Osaka (JP)

(21) Appl. No.: 14/117,329

(22) PCT Filed: May 9, 2012
(86) PCT No.: PCT/JP2012/061842

§ 371 Date: Nov. 12, 2013

(30) Foreign Application Priority Data
May 13, 2011 (JP) 2011-108466

(51) Int. Cl. H01L 29/778; H01L 29/423; H01L 29/417; H01L 29/20; H01L 29/205

(52) U.S. Cl. CPC H01L 29/7787; H01L 29/2003; H01L 29/205; H01L 29/41758; H01L 29/42372

(57) ABSTRACT

In this GaN-based HFET, 2DEG (2-Dimensional Electron Gas) exclusion regions (31) in which no 2DEG is present are formed in the GaN-based multilayered body (5) under regions which are positioned lengthwise outer than imaginary lines (M1, M2) extended from lengthwise ends (11A, 11B) of drain electrodes (11) in a widthwise direction orthogonal to the lengthwise direction and which are adjacent to source electrodes (12), as well as in the GaN-based multilayered body (5) under regions which are lengthwise outwardly adjacent to the lengthwise ends (11A, 11B) of the drain electrodes (11). By the presence of the 2DEG exclusion region (31), concentration of electron flows from end portions of the source electrodes (12) toward end portions of the drain electrodes (11) due to dynamic electric field variations on switching operations can be avoided.

### TECHNICAL FIELD

The present invention relates to a GaN-based HFET (Heterojunction Field-Effect Transistor).

### BACKGROUND ART

As shown in FIG. 19, a conventional GaN-based HFET, in which a source electrode 301 and a drain electrode 302 are formed each into a comb-type finger structure, is disclosed in PTL1 (JP 2010-186925 A). The source electrode 301 is made up of a plurality of source electrode fingers 303 and a source connecting portion 305 to which one end of each of the plurality of source electrode fingers 303 is connected. Also, the drain electrode 302 is made up of a plurality of drain electrode fingers 306 and a drain connecting portion 307 to which one end of each of the plurality of drain electrode fingers 306 is connected. In FIG. 19, a gate electrode to be interposed between the drain electrode fingers 306 and the source electrode fingers 303 is omitted. This GaN-based HFET, in which the source electrode fingers 303 and the drain electrode fingers 306 are included each in plurality to make up a comb-type finger structure, has realized a power device capable of large-current operations.

### CITATION LIST

### Patent Literature

PTL1: JP 2010-186925 A

### SUMMARY OF INVENTION

### Technical Problem

In recent years, there have been obtained GaN-based HFETs of high withstand voltages having OFF-state static withstand voltages (OFF withstand voltages) as high as over 600 V. The static OFF withstand voltage represents, in an OFF state that −10 V remains being applied to the gate electrode in a normally-ON GaN-based HFET, at what volts of a voltage applied to the drain electrode the HFET yields a dielectric breakdown while a voltage of 0 volts is applied to the source electrode. The dielectric breakdown at this static OFF withstand voltage occurs in regions where the source electrode fingers 303 and the drain electrode fingers 306 shown in FIG. 19 face each other.

However, through discussions about GaN-based FETs, the inventors have encountered a problem that a dynamic withstand voltage for switching operation related to short-circuit bearing amounts is a third to a quarter of the OFF-state static withstand voltage.

Concretely, with a normally-ON GaN-based HFET, under the conditions that the voltage applied to the source electrode is set to 0 (V) and the voltage applied to the drain electrode is set to X (V), only one pulse of 0 V pulse wave with a pulse width of 5 psec is applied to the gate electrode in an OFF-state that −10 (V) is applied to the gate electrode, so that the GaN-based HFET is turned on. With this process applied, an experiment was performed to observe whether or not the device would break down. While the voltage X (V) applied to the drain electrode was incremented from 100 V to 110 V to 120 V, . . . , i.e. in steps of 10 V as an example, the experiment was performed at the individual drain applied voltages X (V) so that voltages X (V) causing dielectric breakdown were measured. Herein, dielectric breakdown voltage X (V) determined by the above-described experiment with the pulse wave application is referred to as dynamic withstand voltage.

As a result of this dynamic withstand voltage experiment, it proved that whereas the OFF-state static withstand voltage was 600 V, the dynamic withstand voltage decreased to a quarter (150 V) of the OFF-state static withstand voltage, which was an unexpected phenomenon. Through analysis of samples after this experiment, occurrence of dielectric breakdown at end portions of the drain electrode was observed. As illustrated in FIG. 19, since a distance between an end portion 306A of each drain electrode finger 306 and the source connecting portion 305 was longer (e.g., 1.5 times longer) than an opposing distance between a drain electrode finger 306 and a source electrode finger 303, the occurrence of dielectric breakdown at end portions of the drain electrode was unexpected.

Thus, the inventors made various discussions about decreases in the dynamic withstand voltage, which is a dynamic withstand voltage corresponding to the static OFF withstand voltage, and resultantly presumed as follows. That is, it was considered that currents would be concentrated locally as illustrated by arrows Y in FIG. 19 by influences of time variations of the electric field due to switching operations resulting when the pulse wave was applied to the gate electrode, causing occurrence of dielectric breakdown at end portions of the drain electrode. That is, decreases in the dynamic withstand voltage were considered to be due to influences of current concentrations on switching operations.

Accordingly, an object of the present invention is to provide a GaN-based HFET capable of suppressing decreases in the dynamic withstand voltage.

### Solution to Problem

Based on a presumption that decreases in the dynamic withstand voltage are due to concentration of electron flows to end portions of the drain electrode as described above, which was obtained through various discussions about the issue of decreases in the dynamic withstand voltage, the inventors have invented a structure for suppressing the concentration of electron flows to the drain-electrode end portions. With the structure of this invention, a result effective for suppression of decreases in the dynamic withstand voltage was obtained.

More specifically a heterojunction field-effect transistor comprises:

a GaN-based multilayered body having a heterojunction;
a finger-like drain electrode formed on the GaN-based multilayered body;

a finger-like source electrode formed on the GaN-based multilayered body so as to neighbor the drain electrode in a direction intersecting a lengthwise direction in which the drain electrode extends, the source electrode also extending in the lengthwise direction; and

a gate electrode formed between the drain electrode and the source electrode as viewed in a plan view of the heterojunction field-effect transistor, wherein

a 2DEG (2-Dimensional Electron Gas) exclusion region in which no 2DEG is present is formed in at least either one of:

a portion of the GaN-based multilayered body under a region which is positioned lengthwise outer than an imaginary line extended from a lengthwise end of the drain electrode in a widthwise direction orthogonal to the lengthwise direction and which is adjacent to the source electrode; and

a portion of the GaN-based multilayered body under a region which is lengthwise outwardly adjacent to the lengthwise end of the drain electrode.

Although theoretical, certain grounds are unknown, it has proved, as a concrete fact, that decreases in the dynamic withstand voltage can be suppressed by the structure that the 2DEG exclusion region in which no 2DEG is present is formed as in the present invention.

According to the constitution of the invention, it is conceived that by the presence of the 2DEG exclusion region, electron flows are less likely to be concentrated from the end of the source electrode toward the end of the drain electrode due to dynamic electric field variations on switching operations.

It is noted that the wording “a region adjacent to a source electrode” herein refers to a region in contact with the source electrode with no distance therebetween or a region adjacent to the source electrode with a slight distance therebetween. This slight distance is 20 μm or less as an example, and the 2DEG exclusion region can be produced, for example, by forming recesses in the GaN-based multilayered body or by injecting impurities therein.

In a heterojunction field-effect transistor according to one embodiment,

the 2DEG exclusion region in which no 2DEG is present is formed at least in the GaN-based multilayered body under a region which is lengthwise outwardly adjacent to a lengthwise end of the source electrode.

According to this embodiment, by the presence of the 2DEG exclusion region that is lengthwise outwardly adjacent to the source electrode, can be considered, electron flows are less likely to be concentrated from the lengthwise end of the source electrode toward the lengthwise end of the drain electrode. Thus, decreases in the dynamic withstand voltage can be suppressed.

In a heterojunction field-effect transistor according to one embodiment,

a lengthwise length of the source electrode is equal to a lengthwise length of the drain electrode, or the lengthwise length of the source electrode is shorter than the lengthwise length of the drain electrode,

an imaginary line extended from a lengthwise first end of the source electrode in the widthwise direction orthogonal to the lengthwise direction is in contact with the drain electrode or intersects the drain electrode, and

an imaginary line extended from a second end of the source electrode in the widthwise direction orthogonal to the lengthwise direction is in contact with the drain electrode or intersects the drain electrode.

With such constitution of this embodiment, although theoretical, certain grounds are unknown, it has proved, as a concrete fact, that decreases in the dynamic withstand voltage can be further suppressed. According to the structure in which lengthwise both ends of the source electrode are kept from protruding lengthwise outer than lengthwise both ends of the drain electrode as in this embodiment, it is conceived that electron flows are less likely to be concentrated from an end portion of the source electrode toward an end portion of the drain electrode due to dynamic electric field variations on switching operations.

In contrast to this, in a case where lengthwise both ends or one end of source electrode is protruded lengthwise outer than lengthwise both ends of drain electrode, for example, where the lengthwise length of source electrode is longer than the lengthwise length of drain electrode, it proved that the dynamic withstand voltage decreases considerably, as compared with the structure of this embodiment.

In a heterojunction field-effect transistor according to one embodiment,

the gate electrode, as seen in the plan view, extends in the lengthwise direction between the finger-like drain electrode and the finger-like source electrode and moreover extends so as to surround a lengthwise end portion of the drain electrode.

According to this embodiment, since the gate electrode extends so as to surround the lengthwise end portion of the drain electrode, concentration of electric fields toward the end portion of the drain electrode can be suppressed during the OFF withstand voltage test, so that the static OFF withstand voltage can be improved.

In a heterojunction field-effect transistor according to one embodiment,

the 2DEG exclusion region in which no 2DEG is present is formed in the GaN-based multilayered body under a region surrounded by the imaginary line extended from the lengthwise end of the drain electrode in the widthwise direction orthogonal to the lengthwise direction and the gate electrode.

According to this embodiment, by the structure that the 2DEG exclusion region is formed between lengthwise end of the drain electrode and the gate electrode, it is considered, concentration of electron flows toward the end portions of the drain electrode can be suppressed during the dynamic withstand voltage test, so that the dynamic withstand voltage can be improved. Also, by the presence of the 2DEG exclusion region, the possibility that electric fields between the lengthwise end of the drain electrode and the gate electrode rapidly increases when the distance between the lengthwise end of the drain electrode and the gate electrode is set to a short one can be avoided, so that decreases in the static OFF withstand voltage can be avoided.

In a heterojunction field-effect transistor according to one embodiment,

the 2DEG due to the heterojunction is left remaining in the GaN-based multilayered body under a region surrounded by the imaginary line extended from the lengthwise end of the drain electrode in the widthwise direction orthogonal to the lengthwise direction and the gate electrode.

According to this embodiment, by the structure that 2DEG is left remaining in the GaN-based multilayered body under the region between the lengthwise end of the drain electrode and the gate electrode, increases in current capacity can be achieved as compared with the case where the 2DEG under the region is extinguished. Also, when the distance between the drain electrode and the gate electrode is set to a long one, electric fields between the drain electrode and the gate electrode rapidly decrease, so that the static OFF withstand voltage can be improved.

In a heterojunction field-effect transistor according to one embodiment,

a lengthwise one-side end portion of the finger-like source electrode is positioned lengthwise outer than an imaginary line extended from a lengthwise one-side end of the finger-like drain electrode in the widthwise direction orthogonal to the lengthwise direction, and

the 2DEG exclusion region is formed in the GaN-based multilayered body under a region which is positioned lengthwise outer than an imaginary line extended from the lengthwise one-side end of the drain electrode in the widthwise direction orthogonal to the lengthwise direction and which is widthwise adjacent to the end portion of the source electrode.

According to this embodiment, the 2DEG exclusion region is formed under region widthwise adjacent to the end portion of the source electrode, concentration of electron flows from the end portion of the source electrode toward a end portion of the drain electrode can be suppressed, so that the dynamic OFF withstand voltage can be improved even if a lengthwise one-side end of the source electrode is protruded lengthwise outer than a lengthwise one-side end of the drain electrode.

### Advantageous Effects of Invention

According to the field-effect transistor of the invention, it proved that by 2DEG exclusion region being formed in the GaN-based multilayered body under at least one of region adjacent to the source electrode and region adjacent to lengthwise ends of the drain electrode, decreases in the dynamic withstand voltage can be suppressed. According to the structure of the invention, it is inferred that by the presence of the 2DEG exclusion region, electron flows are less likely to be concentrated from the end portion of the source electrode toward the end portion of the drain electrode due to dynamic electric field variations on switching operations.

### BRIEF DESCRIPTION OF DRAWINGS

FIG. 1 is a schematic plan view of a GaN HFET which is a first embodiment according to the present invention;

FIG. 2 is a sectional view taken along the line B-B of FIG. 1;

FIG. 3 is a sectional view taken along the line A-A of FIG. 1;

FIG. 4 is a sectional view taken along the line C-C of FIG. 1;

FIG. 5 is a sectional view taken along the line D-D of FIG. 1;

FIG. 6 is a schematic plan view of a first modification of the first embodiment;

FIG. 7 is a schematic plan view of a second modification of the first embodiment;

FIG. 8 is a schematic plan view of a GaN HFET which is a second embodiment according to the invention;

FIG. 9 is a sectional view taken along the line E-E of FIG. 8;

FIG. 10 is a sectional view taken along the line F-F of FIG. 8;

FIG. 11 is a schematic plan view of a modification of the second embodiment;

FIG. 12 is a schematic plan view of a GaN HFET which is a third embodiment according to the invention;

FIG. 13 is a sectional view taken along the line G-G of FIG. 12;

FIG. 14 is a sectional view taken along the line H-H of FIG. 12;

FIG. 15 is a sectional view taken along the line I-I of FIG. 12;

FIG. 16 is a sectional view taken along the line J-J of FIG. 12;

FIG. 17 is a schematic plan view of a comparative example of the second embodiment;

FIG. 18 is a graph showing a relationship of a distance between an end of the drain electrode and the connecting portion of the gate electrode in the second modification of the first embodiment as well as in the second embodiment, against the electric field E; and

FIG. 19 is a schematic plan view of an electrode structure according to a back ground art example.

### DESCRIPTION OF EMBODIMENTS

Hereinbelow, the present invention will be described in detail by way of embodiments thereof illustrated in the accompanying drawings.

### First Embodiment

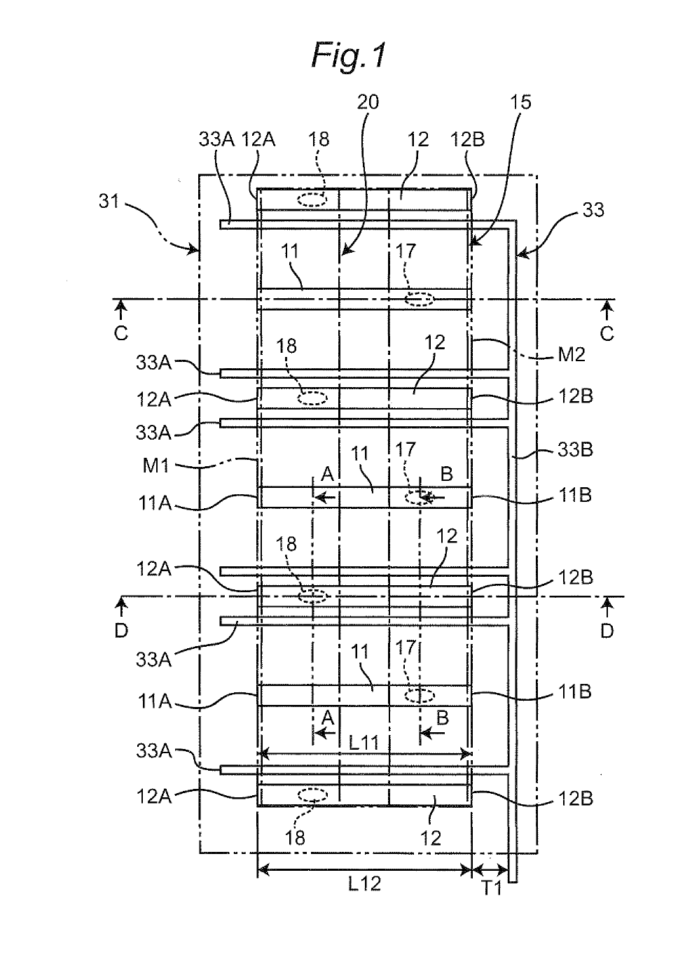

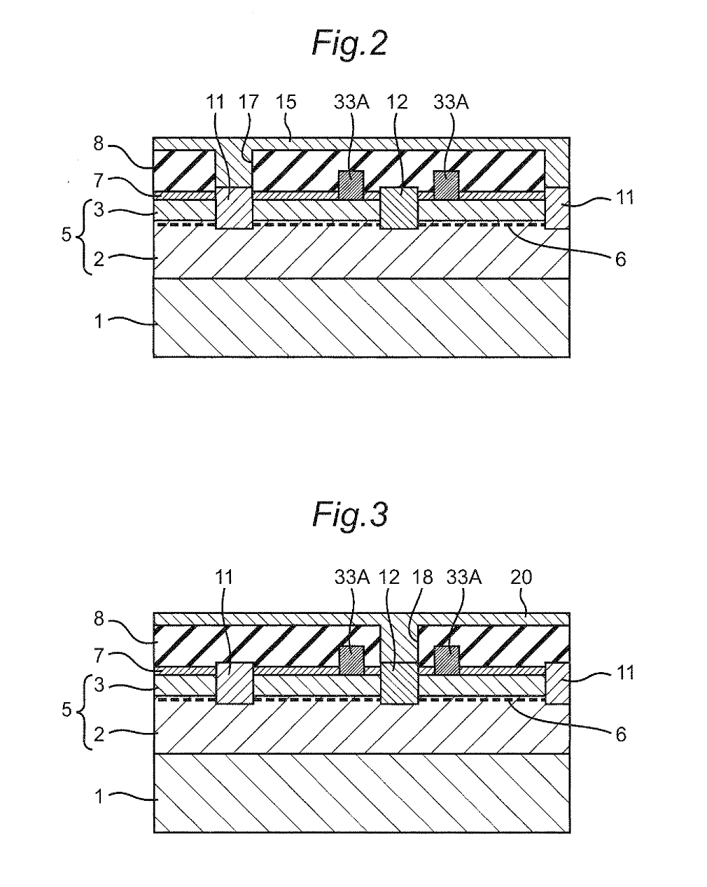

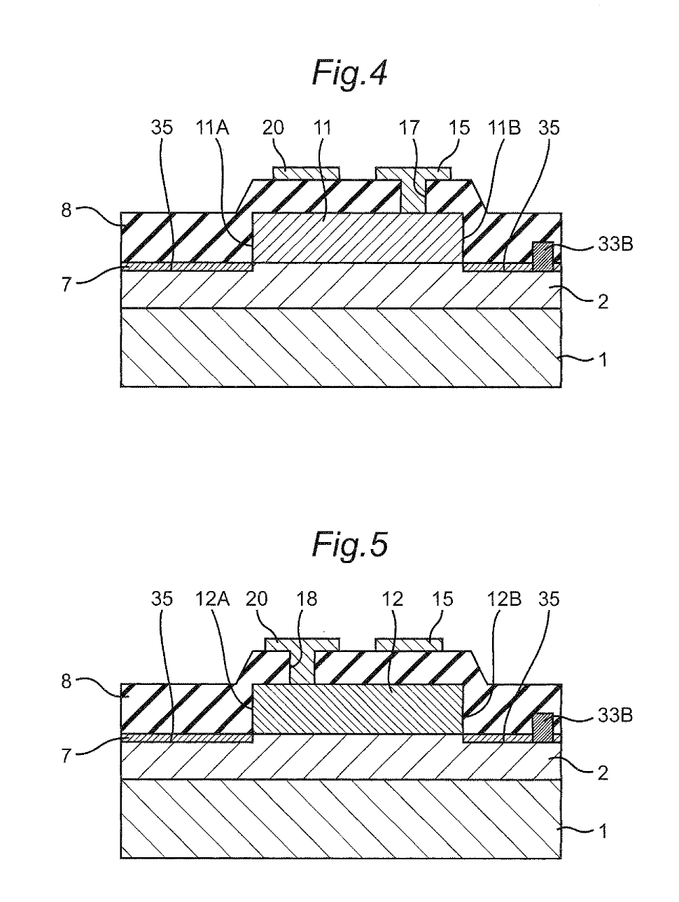

FIG. 1 is a schematic plan view of a GaN HFET which is a first embodiment of the invention. FIG. 2 is a sectional view taken along the line B-B of FIG. 1, and FIG. 3 is a sectional view taken along the line A-A of FIG. 1. FIG. 4 is a sectional view taken along the line C-C of FIG. 1, and FIG. 5 is a sectional view taken along the line D-D of FIG. 1.

As shown in FIGS. 2 and 3, in this first embodiment, an undoped GaN layer 2 and an undoped AlGaN layer 3 are formed on a Si substrate 1. The undoped GaN layer 2 and the undoped AlGaN layer 3 constitute a GaN-based multilayered body 5 having a heterojunction. A 2DEG (2-Dimensional Electron Gas) 6 is generated at an interface between the undoped GaN layer 2 and the undoped AlGaN layer 3. Also, a protective film 7 and an interlayer insulating film 8 are formed one by one on the GaN-based multilayered body 5. Material of the protective film 7, for which SiN is used as an example in this case, may also be SiO₂, Al₂O₃, or the like. Also, material of the interlayer insulating film 8, for which polyimide is used as an example in this case, may be an insulating material such as SOG (Spin On Glass) or BPSG (Boron Phosphorous Silicate Glass). Film thickness of the SiN protective film 7, which is set to 150 nm as an example in this case, may also be set within a range of 20 nm-250 nm.

Recesses reaching the undoped GaN layer 2 are formed in the GaN-based multilayered body 5. In the recesses, drain electrodes 11 and source electrodes 12 are formed as ohmic electrodes. The drain electrodes 11 and the source electrodes 12 are provided each as a Ti/Al/TiN electrode as an example, in which Ti layer, Al layer and TiN layer are stacked one by one. Also, openings are formed in the protective film 7, and a gate electrode 33 is formed in the openings. The gate electrode 33 is formed of, for example, TiN so as to be a Schottky electrode having Schottky junction with the undoped AlGaN layer 3.

As shown in FIG. 2, a drain interconnection 15 is formed on the interlayer insulating film 8. Through holes 17 are formed in the interlayer insulating film 8, and the drain interconnection 15 is electrically connected to the drain electrodes 11 via the through holes 17. Also as shown in FIG. 3, a source interconnection 20 is formed on the interlayer insulating film 8. Through holes 18 are formed in the interlayer insulating film 8, and the source interconnection 20 is electrically connected to the source electrodes 12 via the through holes 18. Ti/Au or Ti/Al or the like is used for the drain interconnection 15 and the source interconnection 20.

As shown in FIG. 1, the three-finger like drain electrodes 11 and the four-finger like source electrodes 12 are included in this first embodiment. The drain electrodes 11 and the source electrodes 12 are alternately placed so as to be apart from each other with a predetermined distance in a widthwise direction orthogonal to the direction in which the drain electrodes 11 and the source electrodes 12 extend in finger-like shape. Besides, the drain electrodes 11 and the source electrodes 12 extend generally parallel to each other.

Also in this embodiment, a lengthwise length L12 of each source electrode 12 and a lengthwise length L11 of each drain electrode 11 are equal to each other. Besides, imaginary lines M1, M2 extended from lengthwise both ends 12A, 12B of the source electrodes 12 in a widthwise direction orthogonal to the lengthwise direction are in contact with ends 11A, 11B of the drain electrodes 11. That is, lengthwise positions of the lengthwise ends 12A, 12B of the source electrodes 12 are coincident with lengthwise positions of the lengthwise ends 11A, 11B of the drain electrodes 11.

The gate electrode 33, as seen in a plan view, has a plurality of lengthwise extending portions 33A extending lengthwise between the finger-like drain electrodes 11 and the finger-like source electrodes 12, as well as a connecting portion 33B that connects the lengthwise extending portions 33A. This connecting portion 33B extends in the widthwise direction orthogonal to the lengthwise direction lengthwise outside the drain electrodes 11 and the source electrodes 12. As shown in FIG. 1, each lengthwise extending portion 33A of the gate electrode 33 has a widthwise distance to the source electrode 12 shorter than its widthwise distance to the drain electrode 11.

In this first embodiment also, as shown in FIGS. 4 and 5, recesses 35 reaching the undoped GaN layer 2 are formed so as to extend over a range from regions lengthwise outwardly adjacent to the lengthwise ends 11A, 11B of each drain electrode 11 to regions lengthwise outwardly adjacent to lengthwise both ends 12A, 12B of each source electrode 12. By these recesses 35, a 2DEG exclusion region 31 from which 2DEG has been excluded shown in FIG. 1 is formed. This 2DEG exclusion region 31 extends in the widthwise direction lengthwise outward of the imaginary line M1 and moreover extends in the widthwise direction lengthwise outward of the imaginary line M2. Therefore, the 2DEG exclusion region 31 is formed under regions lengthwise outwardly adjacent to lengthwise both ends 12A, 12B of each source electrode 12, as well as under regions lengthwise outwardly adjacent to lengthwise both ends 11A, 11B of each drain electrode 11. Further, also in regions widthwise outwardly adjacent to widthwise both ends of the source electrodes 12, the 2DEG exclusion region 31 extends in the lengthwise direction along the source electrodes 12.

The GaN HFET having the above-described structure, being the normally-ON type, is turned off with a negative voltage applied to the gate electrode 13. With this GaN HFET, it has proved that the formation of the 2DEG exclusion region 31 makes it possible to suppress decreases in the dynamic withstand voltage in comparison to the prior art example as described below.

More specifically, in such a prior art example as shown in FIG. 19, it has been the case that although a voltage of 600 V can be obtained as a static OFF withstand voltage, yet the dynamic withstand voltage, which is the dynamic OFF withstand voltage, decreases to 150 V or less.

This static OFF withstand voltage represents what volts is the voltage that causes a short-circuit (dielectric breakdown) when applied to the drain electrodes while 0 V is applied to the source electrodes in an OFF state that −10 V keeps being applied to the gate electrode. Meanwhile, the dynamic withstand voltage is determined by observing whether or not the device breaks down as a result of performing an experiment, as described before, in which under the conditions that the voltage applied to the source electrodes is set to 0 (V) and the voltage applied to the drain electrodes is set to X (V), only one pulse of 0 V pulse wave with a pulse width of 5 psec is applied to the gate electrode in an OFF-state that −10 (V) is applied to the gate electrode, so that the GaN HFET is turned on. The voltage X (V) applied to the drain electrodes was incremented from 100 V to 110 V to 120 V, . . . , i.e. in steps of 10 V as an example, the experiment was performed at the individual drain applied voltages X (V) so that voltages X (V) causing dielectric breakdown were measured.

In the prior art example, as a result of this experiment, whereas the OFF-state static withstand voltage was 600 V, the dynamic withstand voltage decreased to a quarter (150 V) or less of the OFF-state static withstand voltage, which was an unexpected phenomenon. Through analysis of samples after this experiment, occurrence of dielectric breakdown at end portions of the drain electrodes was observed. Decreases in the dynamic withstand voltage against the static OFF withstand voltage in the prior art example are presumed as follows. That is, it is considered that currents are locally concentrated due to time variations of the electric field due to switching operations resulting when the pulse wave is applied to the gate electrode, causing occurrence of dielectric breakdown at end portions of the drain electrodes. That is, the decreases in the withstand voltage are considered to be due to influences of dynamic electric field variations on switching operations.

In contrast to this, in this embodiment, it proved that the static OFF withstand voltage was 600 V while the dynamic withstand voltage was 260 V. Therefore, this embodiment showed an improvement of 70% or more in the dynamic withstand voltage, which is the dynamic OFF withstand voltage, over the prior art example.

According to the structure of this embodiment, it can be inferred that by the presence of the 2DEG exclusion region 31, electron flows are less likely to be concentrated from the ends 12A, 12B of the source electrodes 12 toward the ends 11A, 11B of the drain electrodes 11 due to dynamic electric field variations on switching operations. Also according to this embodiment, it is considered that concentration of electron flows from the ends 12A, 12B of the source electrodes 12 toward the ends 11A, 11B of the drain electrodes 11 can be avoided by the structure that lengthwise both ends 12A, 12B of the source electrodes 12 do not protrude lengthwise outward of lengthwise both ends 11A, 11B of the drain electrodes 11.

Also in this embodiment, with finger-like drain electrodes 11 and source electrodes 12 provided in plurality, and with the above-described structure that lengthwise both ends 12A, 12B of the source electrodes 12 do not protrude lengthwise outward of lengthwise both ends 11A, 11B of the drain electrodes 11, electron flows are less likely to be concentrated from both-side source electrodes 12 toward end portions of the central drain electrodes 11 due to dynamic electric field variations on switching operations. Thus, remarkable improvement in the dynamic withstand voltage can be obtained.

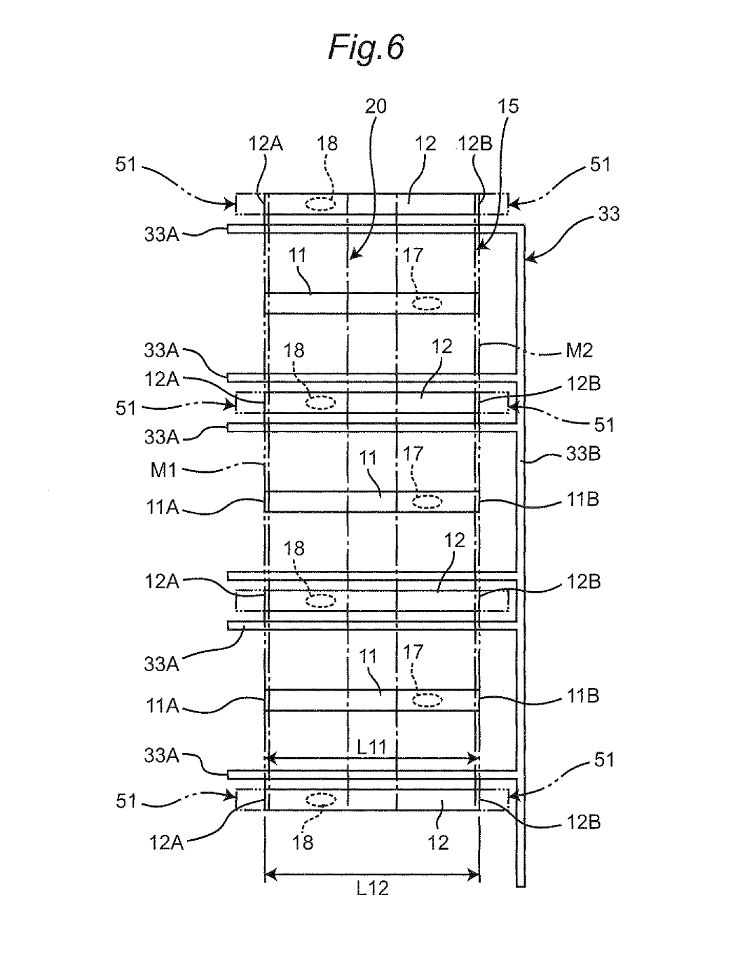

In the first embodiment, the 2DEG exclusion region 31 is formed under regions lengthwise outwardly adjacent to lengthwise both ends 12A, 12B of the source electrodes 12 as well as under regions lengthwise outwardly adjacent to lengthwise both ends 11A, 11B of the drain electrodes 11. However, as shown in a first modification shown in FIG. 6, a 2DEG exclusion region 51 may be formed only under regions lengthwise outwardly adjacent to lengthwise both ends 12A, 12B of the source electrodes 12. Also in this first modification, it is considered that concentration of electron flows from lengthwise both ends 12A, 12B of the source electrodes 12 toward lengthwise both ends 11A, 11B of the drain electrodes 11 can be avoided, so that the dynamic OFF withstand voltage can be improved. In addition, not only the 2DEG exclusion region 51 under the region lengthwise adjacent to both ends 12A, 12B of the source electrodes 12 but also a 2DEG exclusion region (not shown) under regions adjacent to both ends 11A, 11B of the drain electrodes 11 may also be formed. It is also allowable that the 2DEG exclusion region is formed under a region lengthwise adjacent to only one lengthwise end of the source electrodes 12 or the drain electrodes 11.

In the first embodiment, the 2DEG exclusion region 31 is formed by forming the recesses 35 reaching the undoped GaN layer 2. However, the 2DEG exclusion region 31 may also be formed by injecting impurities such as boron (B) or iron (Fe) into the GaN-based multilayered body 5 of the above-described regions, instead of forming the recesses 35.

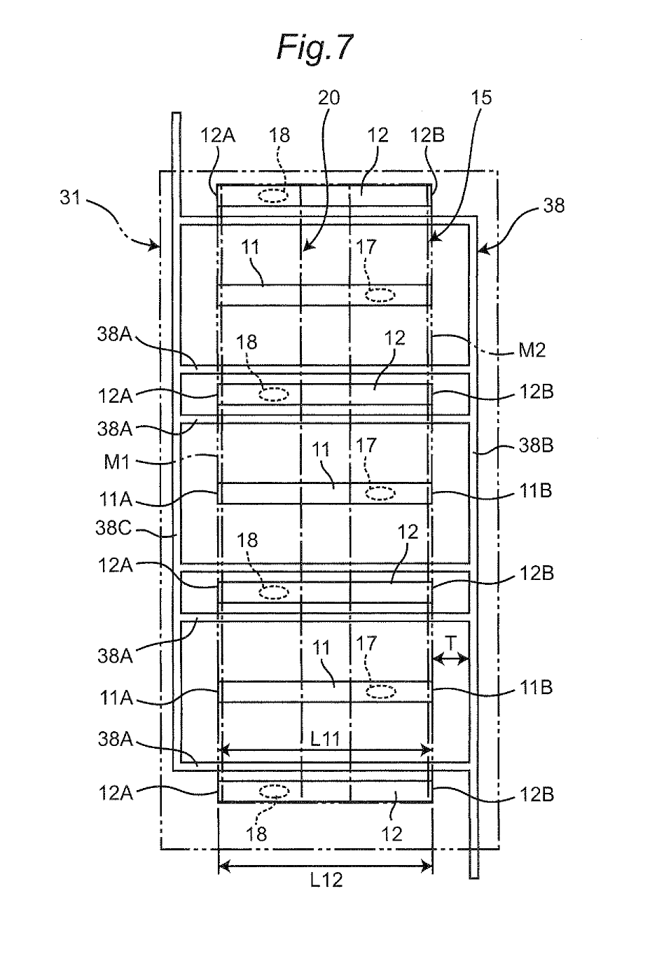

Also as in a second modification shown in FIG. 7, a gate electrode 38 may be provided instead of the gate electrode 33 of the first embodiment. This gate electrode 38, like the gate electrode 33, has a plurality of lengthwise extending portions 38A extending lengthwise between the finger-like drain electrodes 11 and the finger-like source electrodes 12, as well as a connecting portion 38B that connects the lengthwise extending portions 38A. On the other hand, the gate electrode 38, differing from the gate electrode 33, has another connecting portion 38C extending in the widthwise direction as opposed to the connecting portion 38B with the lengthwise extending portions 38A interposed therebetween. This gate electrode 38 surrounds peripheries of each drain electrode 11 including both ends 11A, 11B of the drain electrodes 11 as well as peripheries of each source electrode 12 including both ends 12A, 12B of the source electrodes 12. As a result of this, it is considered, concentration of electron flows toward the end portions of the drain electrodes 11 is suppressed during the OFF withstand voltage test, so that the static OFF withstand voltage can be improved.

In the first embodiment also, the lengthwise length L12 of each source electrode 12 is set equal to the lengthwise length L11 of each drain electrode 11, while the lengthwise positions of the lengthwise ends 12A, 12B of the source electrodes 12 are set coincident with the lengthwise positions of the lengthwise ends 11A, 11B of the drain electrodes 11. However, the lengthwise length of the source electrodes 12 may also be set shorter than the lengthwise length of the drain electrodes 11. In this case, the source electrodes and the drain electrodes are so placed that imaginary lines extended from lengthwise both ends 12A, 12B of the source electrodes 12 in a widthwise direction orthogonal to the lengthwise direction intersect the drain electrodes 11. Also, with the lengthwise length of the source electrodes 12 set shorter than the lengthwise length of the drain electrodes 11, an imaginary line extended in the widthwise direction from one of lengthwise both ends 12A, 12B of the source electrode 12 may be in contact with the lengthwise ends of the drain electrodes 11 while an imaginary line extended in the widthwise direction from the other of both ends 12A, 12B may intersect the drain electrodes 11.

### Second Embodiment

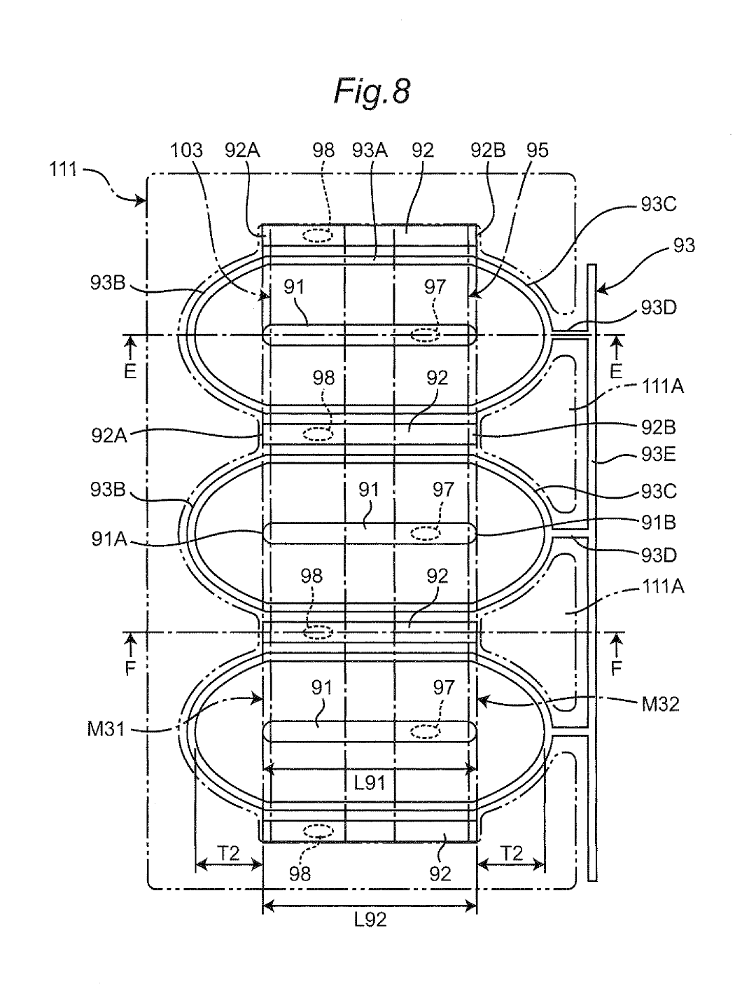

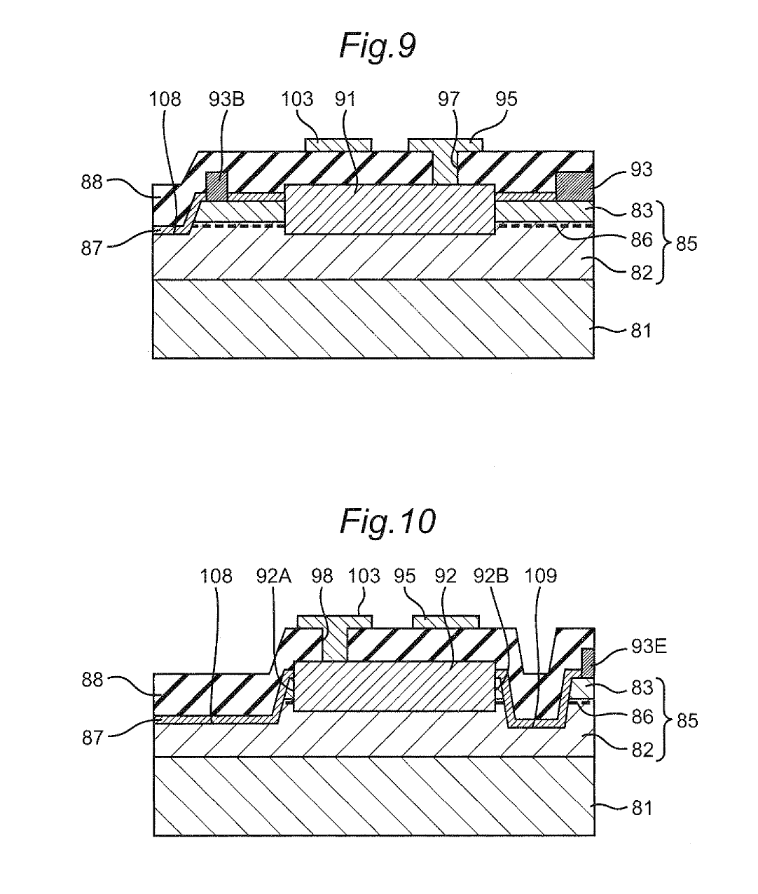

FIG. 8 is a schematic plan view of a GaN HFET which is a second embodiment according to the invention. FIG. 9 is a sectional view taken along the line E-E of FIG. 8. FIG. 10 is a sectional view taken along the line F-F of FIG. 8.

As shown in FIGS. 9 and 10, in this second embodiment, an undoped GaN layer 82 and an undoped AlGaN layer 83 are formed on a Si substrate 81. The undoped GaN layer 82 and the undoped AlGaN layer 83 constitute a GaN-based multilayered body 85 having a heterojunction. A 2DEG (2-Dimensional Electron Gas) 86 is generated at an interface between the undoped GaN layer 82 and the undoped AlGaN layer 83. Also, a protective film 87 and an interlayer insulating film 88 are formed one by one on the GaN-based multilayered body 85. Material of the protective film 87, for which SiN is used as an example in this case, may also be SiO₂, Al₂O₃, or the like. Also, material of the interlayer insulating film 88, for which polyimide is used as an example in this case, may be an insulating material such as SOG or BPSG. Film thickness of the SiN protective film 87, which is set to 150 nm as an example in this case, may also be set within a range of 20 nm-250 nm.

Recesses reaching the undoped GaN layer 82 are formed in the GaN-based multilayered body 85. In the recesses, drain electrodes 91 and source electrodes 92 are formed as ohmic electrodes. The drain electrodes 91 and the source electrodes 92 are provided each as a Ti/Al/TiN electrode as an example, in which Ti layer, Al layer and TiN layer are stacked one by one. Also, openings are formed in the protective film 87, and a gate electrode 93 is formed in the openings. The gate electrode 93 is formed of, for example, TiN so as to be a Schottky electrode having Schottky junction with the undoped AlGaN layer 83.

As shown in FIG. 9, a drain interconnection 95 is formed on the interlayer insulating film 88. Through holes 97 are formed in the interlayer insulating film 88, and the drain interconnection 95 is electrically connected to the drain electrodes 91 via the through holes 97. Also as shown in FIG. 10, a source interconnection 103 is formed on the interlayer insulating film 88. Through holes 98 are formed in the interlayer insulating film 88, and the source interconnection 103 is electrically connected to the source electrodes 92 via the through holes 98. Ti/Au or Ti/Al or the like is used for the drain interconnection 95 and the source interconnection 103.

As shown in FIG. 8, in this embodiment, a lengthwise length L92 of each source electrode 92 and a lengthwise length L91 of each drain electrode 91 are equal to each other. Besides, imaginary lines M31, M32 extended from lengthwise both ends 92A, 92B of the source electrodes 92 in a widthwise direction orthogonal to the lengthwise direction are in contact with both ends 91A, 91B of the drain electrodes 91. That is, lengthwise positions of the lengthwise ends 92A, 92B of the source electrodes 92 are coincident with lengthwise positions of the lengthwise ends 91A, 91B of the drain electrodes 91. Also, both ends 91A, 91B of each drain electrode 91 are curved so as to be convex outward in the lengthwise direction.

The gate electrode 93 has a lengthwise extending portion 93A extending lengthwise between the finger-like drain electrodes 91 and the finger-like source electrodes 92, as well as curved portions 93B, 93C. The curved portion 93B extends so as to surround the end 91A of each drain electrode 91 and adjoin one-side ends of two lengthwise extending portions 93A neighboring each other with a drain electrode 91 interposed therebetween. Also, the curved portion 93C extends so as to surround an end 91B of each drain electrode 91 and adjoin the other-side ends of two lengthwise extending portions 93A neighboring each other with a drain electrode 91 interposed therebetween. Further, an annular portion composed of the two lengthwise extending portions 93A, the curved portion 93B and the curved portion 93C adjoins a lengthwise extending branch portion 93D, which adjoins a concatenating portion 93E extending in a direction orthogonal to the lengthwise direction. As shown in FIG. 8, each lengthwise extending portion 93A of the gate electrode 93 has a widthwise distance to the source electrode 92 shorter than its widthwise distance to the drain electrode 91.

Further, in this embodiment, as shown in FIG. 8, 2DEG exclusion regions 111, 111A are formed so as to be outer-peripherally apart with slight distances from the curved portions 93B, 93C of the gate electrode 93 and moreover lengthwise outwardly apart with slight distances from both ends 92A, 92B of the source electrodes 92. These slight distances are 20 μm or less as an example. The 2DEG exclusion regions 111, 111A are formed by forming later-described recesses in the GaN-based multilayered body 85.

The 2DEG exclusion region 111 expands lengthwise outwardly wider and wider from a proximity of the end 92A of each source electrode 92 and moreover extends along the curved portion 93B of the gate electrode 93. Also, the 2DEG exclusion region 111A expands lengthwise outwardly wider and wider from a proximity of the end 92B of the source electrode 92 and moreover extends along the curved portion 930 of the gate electrode 93.

In this 2DEG exclusion region 111, as shown in FIG. 9, a recess 108 is formed so as to be outer-peripherally adjacent to the curved portion 93B of the gate electrode 93 and moreover reach the undoped GaN layer 82, by which the 2DEG 86 is excluded. This recess 108, as shown in FIG. 10, is lengthwise outwardly adjacent to the end 92A of the source electrode 92. Also, a recess 109 is formed so as to be lengthwise outwardly adjacent to the end 92B of the source electrode 92 and moreover reach the undoped GaN layer 82, by which the 2DEG 86 is excluded so that the 2DEG exclusion region 111A is formed. Further, the 2DEG exclusion region 111 extends lengthwise along the source electrodes 92 also in regions widthwise outwardly adjacent to widthwise both-end source electrodes 92.

The GaN HFET having the above-described structure, being the normally-ON type, is turned off with a negative voltage applied to the gate electrode 13.

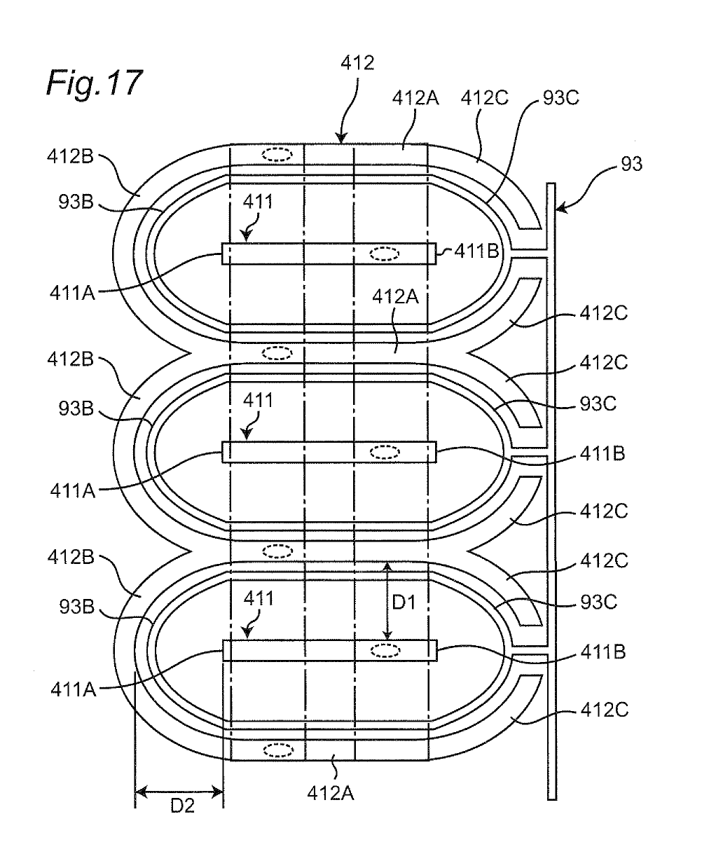

As to a withstand voltage experiment on the GaN HFET of this second embodiment, it proved that the static OFF withstand voltage was 600 V while the dynamic withstand voltage was 300 V, showing an improvement of 100% or more over the dynamic withstand voltage of 150 V of the prior art example shown in FIG. 17.

In the comparative example shown in FIG. 17, unlike the second embodiment, no 2DEG exclusion regions 111, 111A are formed, a source electrode 412 is provided instead of the source electrodes 92, and drain electrodes 411 are provided instead of the drain electrodes 91. The source electrode 412 of this comparative example has lengthwise extending portions 412A corresponding to the source electrodes 92, curved portions 412B each extending from a lengthwise one end of the lengthwise extending portion 412A so as to surround the curved portion 93B of the gate electrode 93, and curved portions 412C each extending from the lengthwise other end of the lengthwise extending portion 412A so as to surround the curved portion 93C of the gate electrode 93. A lengthwise distance D2 between an end 411A of the drain electrode 411 and the curved portion 412B of the source electrode 412 in the comparative example is 1.5 times larger than a widthwise distance D1 between the drain electrode 411 and the lengthwise extending portion 412A of the source electrode 412.

The static OFF withstand voltage of the GaN HFET in this comparative example was 600 V. At this static OFF withstand voltage, there occurred a short-circuit (dielectric breakdown) between the lengthwise extending portions 412A of the source electrode 412 and the drain electrodes 411. On the other hand, the dynamic withstand voltage in this comparative example was 150 V, showing a decrease to a quarter of the static OFF withstand voltage of 600 V. At this dynamic withstand voltage, occurrence of dielectric breakdown at portions of the ends 411A, 411B of the drain electrodes 411 was observed. The decreases in the dynamic withstand voltage against the static OFF withstand voltage in this comparative example is inferred as follows. That is, it is considered that currents are locally concentrated due to time variations of the electric field due to switching operations resulting when the pulse wave is applied to the gate electrode 93, causing occurrence of dielectric breakdown at portions of the ends 411A, 411B of the drain electrodes 411. That is, the decreases in the withstand voltage are conceived to be due to influences of dynamic electric field variations on switching operations.

In contrast to this, the GaN HFET of this embodiment showed that the dynamic withstand voltage was 280 V, showing an improvement of 80% or more over the dynamic withstand voltage of 150 V of the comparative example. It is noted that the static OFF withstand voltage of this embodiment was 600 V, which was equal to that of the comparative example.

As shown above, according to the second embodiment, it proved that decreases in the dynamic withstand voltage can be suppressed as compared with the comparative example.

As to the reason of this, it can be inferred that in addition to the formation of the 2DEG exclusion regions 111, 111A adjacent to lengthwise both ends 92A, 92B of the source electrodes 92, lengthwise both ends 92A, 92B of the source electrodes 92 are kept from protruding lengthwise outward of lengthwise both ends 91A, 91B of the drain electrodes 91 and moreover both ends 91A, 91B of the drain electrodes 91 are curved-shaped, by which concentration of electron flows toward the ends 91A, 91B of the drain electrodes 91 can be suppressed during the dynamic withstand voltage test.

Also according to the second embodiment, the dynamic withstand voltage improved by 20 V, as compared with the foregoing first embodiment. The reason of this is considered not only that the 2DEG exclusion region 111 is formed but also that each drain electrode 91 is entirely surrounded, as in a plan view, by the gate electrode 93 by means of its lengthwise extending portion 93A and curved portions 93B, 93C and moreover that both ends 91A, 91B of the drain electrodes 91 are curved-shaped. With this structure, it is inferred, concentration of electron flows toward the ends 91A, 91B of the drain electrodes 91 can be suppressed during the dynamic withstand voltage test.

In addition, in the second embodiment, the lengthwise length of the source electrodes 92 may be set shorter than the lengthwise length of the drain electrodes 91. In this case, the source electrodes 92 and the drain electrodes 91 are so placed that imaginary lines extended from lengthwise both ends 92A, 92B of the source electrodes 92 in a widthwise direction orthogonal to the lengthwise direction intersect the drain electrodes 91. Also, with the lengthwise length of the source electrodes 92 set shorter than the lengthwise length of the drain electrodes 91, an imaginary line extended in the widthwise direction from one of lengthwise both ends 92A, 92B of the source electrode 92 may be in contact with the lengthwise ends of the drain electrodes 91 while an imaginary line extended in the widthwise direction from the other of both ends 92A, 92B may intersect the drain electrodes 91.

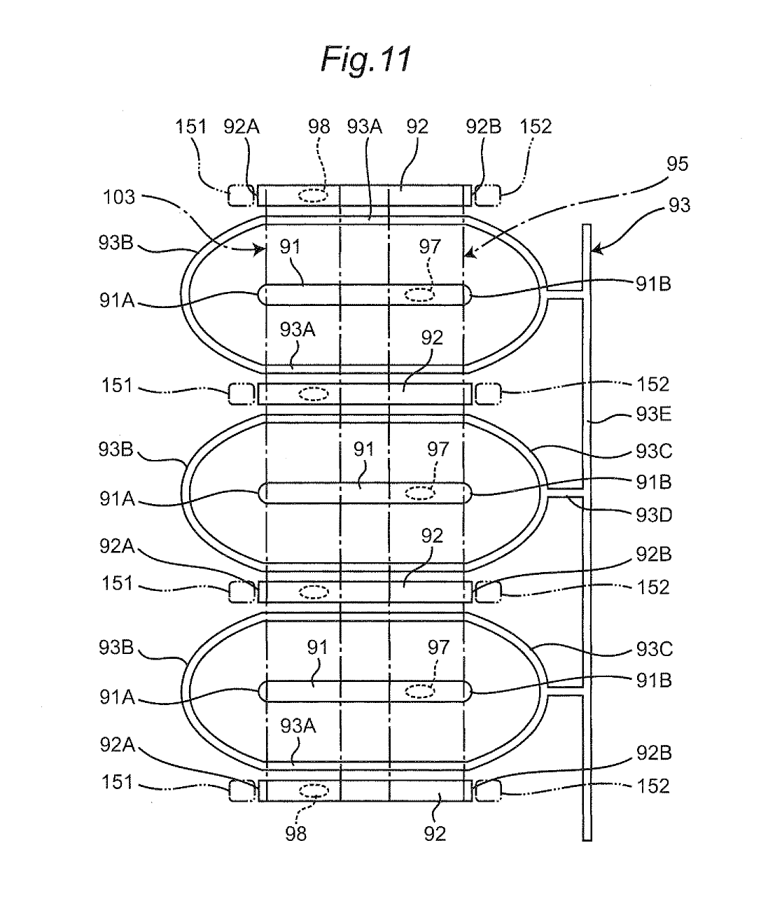

Also in the second embodiment, as shown in FIG. 8, the 2DEG exclusion region 111 is formed so as to be outer-peripherally apart with slight distances from the curved portions 93B, 93C of the gate electrode 93 and moreover lengthwise outwardly apart with slight distances (e.g., 20 μm or less) from both ends 92A, 92B of the source electrodes 92. Alternatively, it is also allowable, as shown in FIG. 11, that 2DEG exclusion regions 151, 152 are formed so as to be lengthwise outwardly apart with slight distances (e.g., 20 μm or less) from both ends 92A, 92B of the source electrodes 92. The 2DEG exclusion regions 151, 152 each have a widthwise length generally equal to the widthwise length of the source electrodes 92 and are generally quadrilateral-shaped. Even with such quadrilateral-shaped 2DEG exclusion regions 151, 152, it is considered, formation of current paths from both ends 92A, 92B of the source electrodes 92 to both ends 91A, 91B of the drain electrodes 91 is suppressed, so that improvement of the dynamic withstand voltage can be achieved. In addition, not only the 2DEG exclusion regions 151, 152 under regions lengthwise adjacent to both ends 92A, 92B of the source electrodes 92 but also 2DEG exclusion regions (not shown) under regions adjacent to both ends 91A, 91B of the drain electrodes 91 may also be formed. Further, 2DEG exclusion regions may be formed under regions lengthwise adjacent only to one-side lengthwise ends of the source electrodes 92 or the drain electrodes 91.

Also in the second embodiment, the 2DEG exclusion regions 111, 111A are formed by forming the recesses 108, 109 reaching the undoped GaN layer 82. However, the 2DEG exclusion regions 111, 111A may also be formed by injecting impurities such as boron (B) or iron (Fe) into the GaN-based multilayered body 85 of the above-described regions, instead of forming the recesses 108, 109.

Further, the 2DEG exclusion region 111 may be not outer-peripherally apart with any distances, but adjacent to the curved portions 93B, 93C of the gate electrode 93, and the 2DEG exclusion regions 111, 111A may be not lengthwise outwardly apart with distances but adjacent to both ends 92A, 92B of the source electrodes 92. Herein, the expression, “a 2DEG exclusion region is adjacent to a source electrode or a gate electrode,” includes both cases where those members are adjacent to each other without any distance or gap and where they are adjacent to each other with a slight distance or gap (e.g., 20 μm or less).

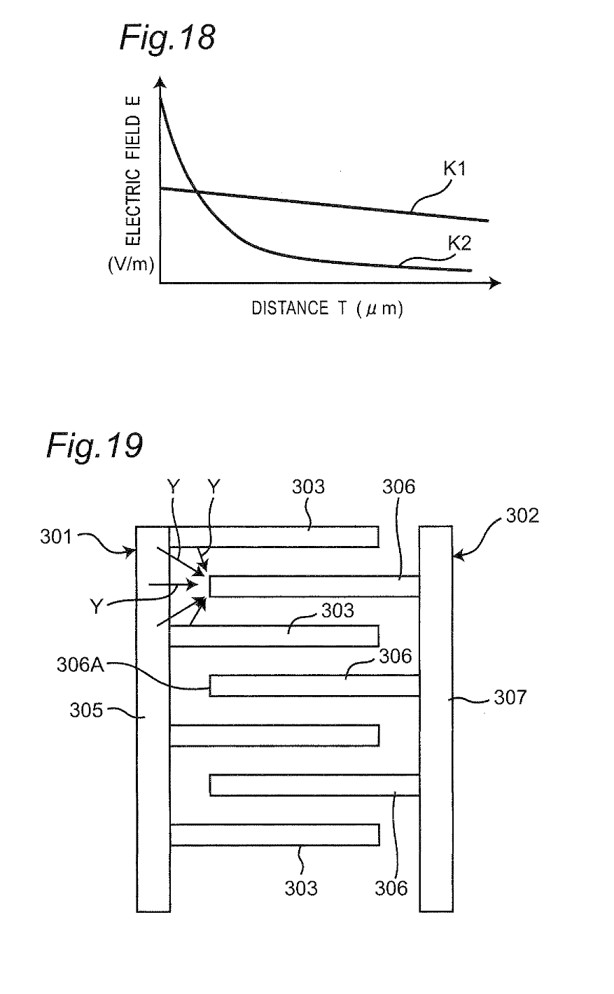

Now a characteristic K2 in FIG. 18 shows a relationship between a distance T2 (μm) from the ends 91A, 91B of the drain electrodes 91 to the curved portions 93B, 93C of the gate electrode 93 and an electric field E (V/m) between the ends 91A, 91B and the curved portions 93B, 93C in this second embodiment. According to the second embodiment, the 2DEG 86 is left remaining in the GaN-based multilayered body 85 under regions between the lengthwise ends 91A, 91B of the drain electrodes 91 and the curved portions 93B, 93C of the gate electrode 93. With this structure, elongating the distance T2 between the drain electrodes 91 and the curved portions 93B, 93C of the gate electrode 93 causes the electric field between the drain electrodes 91 and the curved portions 93B, 93C of the gate electrode 93 to be rapidly decreased, so that the static OFF withstand voltage can be improved.

On the other hand, a characteristic K1 of FIG. 18 represents a relationship between a distance T1 from the ends 11B of the drain electrodes 11 to the connecting portion 33B of the gate electrode 33 and an electric field E between the ends 11B and the connecting portion 33B in the foregoing first embodiment. In the first embodiment, the 2DEG between the ends 11B of the drain electrodes 11 and the connecting portion 33B of the gate electrode 33 is excluded. With this structure, shortening the distance Ti makes it possible to prevent rapid increases in the electric field E so that rapid decreases in the static OFF withstand voltage can be avoided.

### Third Embodiment

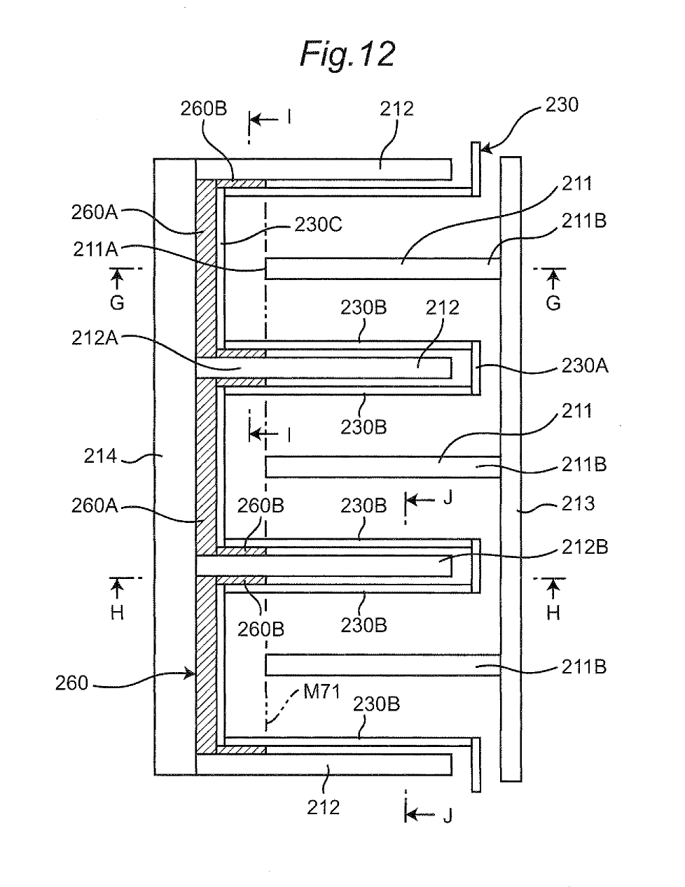

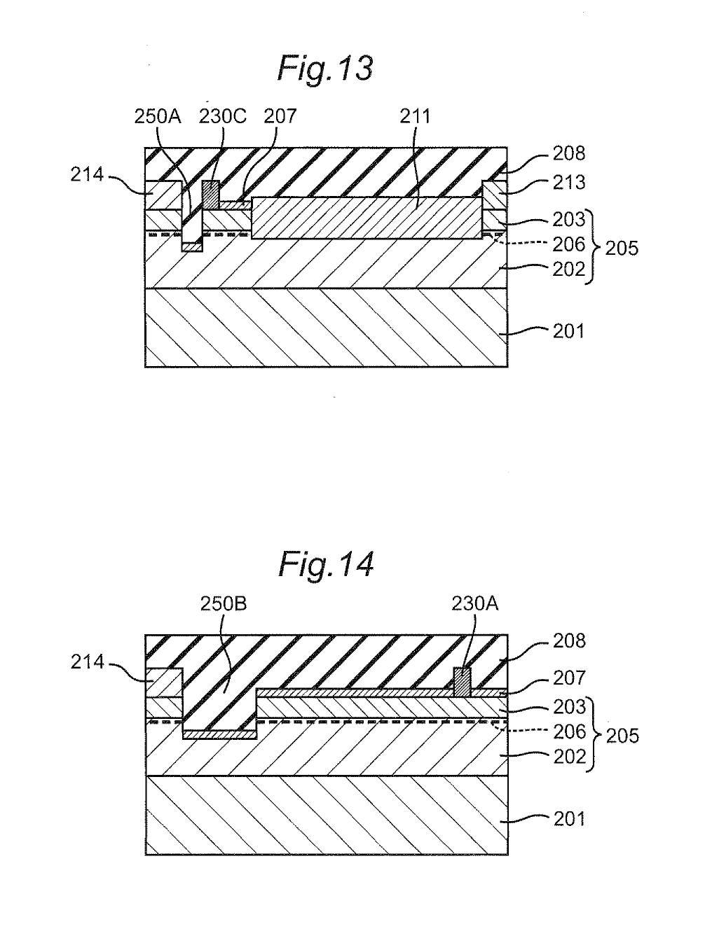

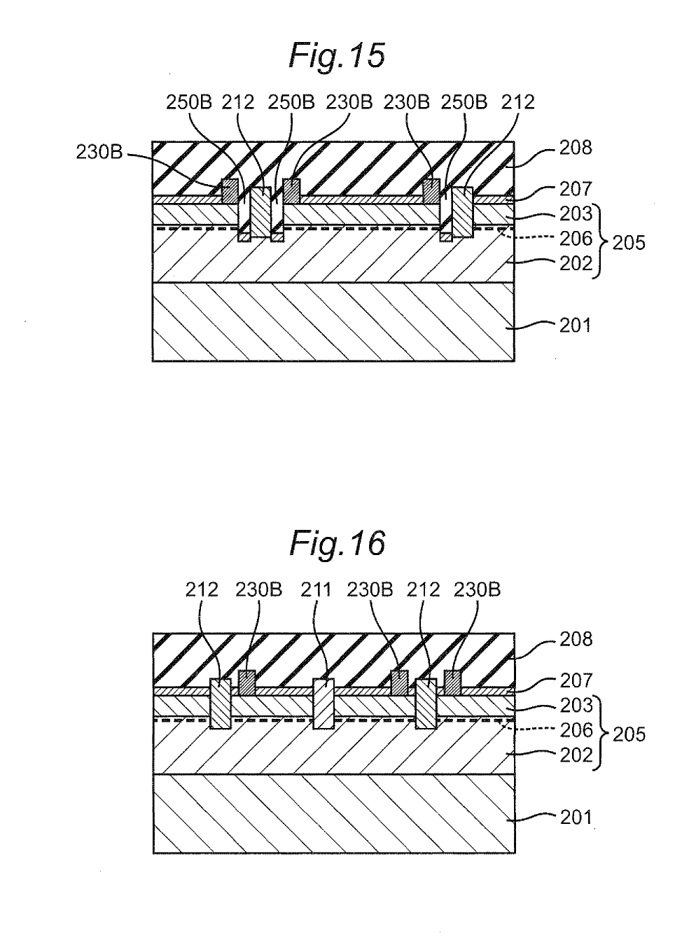

FIG. 12 is a schematic plan view of a GaN HFET which is a third embodiment according to the invention. FIG. 13 is a sectional view taken along the line G-G of FIG. 12, and FIG. 14 is a sectional view taken along the line H-H of FIG. 12. FIG. 15 is a sectional view taken along the line I-I of FIG. 12, and FIG. 16 is a sectional view taken along the line J-J of FIG. 12.

As shown in the sectional views of FIGS. 13 to 16, in this third embodiment, an undoped GaN layer 202 and an undoped AlGaN layer 203 are formed on a Si substrate 201. The undoped GaN layer 202 and the undoped AlGaN layer 203 constitute a GaN-based multilayered body 205 having a heterojunction. A 2DEG (2-Dimensional Electron Gas) 206 is generated at an interface between the undoped GaN layer 202 and the undoped AlGaN layer 203. Also, a protective film 207 and an interlayer insulating film 208 are formed one by one on the GaN-based multilayered body 205. Material of the protective film 207, for which SiN is used as an example in this case, may also be SiO₂, Al₂O₃, or the like. Also, material of the interlayer insulating film 208, for which polyimide is used as an example in this case, may be an insulating material such as SOG (Spin On Glass) or BPSG (Boron Phosphorous Silicate Glass). Film thickness of the SiN protective film 207, which is set to 150 nm as an example in this case, may also be set within a range of 20 nm-250 nm.

Recesses reaching the undoped GaN layer 202 are formed in the GaN-based multilayered body 205. In the recesses, drain electrodes 211 and source electrodes 212 are formed as ohmic electrodes. The drain electrodes 211 and the source electrodes 212 are provided each as a Ti/Al/TiN electrode as an example, in which Ti layer, Al layer and TiN layer are stacked one by one. Also, openings are formed in the protective film 207, and a gate electrode 230 is formed in the openings. The gate electrode 230 is formed of, for example, TiN so as to be a Schottky electrode having Schottky junction with the undoped AlGaN layer 203.

As shown in FIG. 12, the three-finger like drain electrodes 211 and the four-finger like source electrodes 212 are included in this third embodiment. The drain electrodes 211 and the source electrodes 212 are alternately placed so as to be apart from each other with a predetermined distance in a widthwise direction orthogonal to the direction in which the drain electrodes 211 and the source electrodes 212 extend in finger-like shape. Besides, the drain electrodes 211 and the source electrodes 212 extend generally parallel to each other.

Also in this third embodiment, lengthwise one end portion 212A of each source electrode 212 is protruded outer than lengthwise one end 211A of each drain electrode 211 toward the lengthwise one end side. That is, the lengthwise one end portions 212A of the finger-like source electrodes 212 are positioned lengthwise outer than an imaginary line M71 extended from the lengthwise one end 211A of each finger-like drain electrode 211 in a widthwise direction orthogonal to the lengthwise direction.

The lengthwise other end 2118 of each drain electrode 211 is electrically connected to a drain-electrode connecting portion 213 extending in the widthwise direction. Also, the lengthwise one end portion 212A of each source electrode 212 is electrically connected to a source-electrode connecting portion 214 extending in the widthwise direction.

Also, the gate electrode 230, as seen in a plan view, has a plurality of lengthwise extending portions 230B extending lengthwise between the finger-like drain electrodes 211 and the finger-like source electrodes 212, as well as a connecting portion 2300 that connects the lengthwise extending portions 230B by its one end portion and a connecting portion 230A that connects the lengthwise extending portions 230B by its other end portion. The connecting portion 230C extends in the widthwise direction orthogonal to the lengthwise direction lengthwise outside the one end 211A of each drain electrode 211. Also, the connecting portion 230A extends in the widthwise direction orthogonal to the lengthwise direction lengthwise outside the other end portion 212B of each source electrode 212. As shown in FIG. 12, each lengthwise extending portion 230B of the gate electrode 230 has a widthwise distance to the source electrode 212 shorter than its widthwise distance to the drain electrode 211.

As shown in FIG. 14, which is a sectional view taken along the line H-H of FIG. 12, as well as in FIG. 15, which is a sectional view taken along the line I-I of FIG. 12, recesses 250B reaching the undoped GaN layer 202 are formed under regions between one end portions 212A of the source electrodes 212 and the lengthwise extending portions 230B of the gate electrode 230. By these recesses 250B, 2DEG exclusion regions 260E shown in FIG. 12 are formed. These 2DEG exclusion regions 260B are formed in regions of the GaN-based multilayered body 205 which are positioned lengthwise outer than the imaginary line M71 extended in the widthwise direction from the lengthwise one end 211A of the drain electrode 211 and which are widthwise adjacent to the one end portions 212A of the source electrodes 212.

Also as shown in FIG. 13, which is a sectional view taken along the line G-G of FIG. 12, recesses 250A reaching the undoped GaN layer 202 are formed under regions between the source-electrode connecting portion 214 and the lengthwise extending portions 230E of the gate electrode 230. By these recesses 250A, 2DEG exclusion regions 260A shown in FIG. 12 are formed. These 2DEG exclusion regions 260A are lengthwise outwardly adjacent to the 2DEG exclusion regions 260B and extend from the one end portions 212A of the source electrodes 212 in the widthwise direction along the source-electrode connecting portion 214.

In the third embodiment, the 2DEG exclusion regions 260A, 260B are formed by forming the recesses 250A, 250B reaching the undoped GaN layer 202. However, the 2DEG exclusion regions 260A, 260B may also be formed by injecting impurities such as boron (B) or iron (Fe) into the GaN-based multilayered body 205 of the above-described regions, instead of forming the recesses 250A, 250B.

According to the third embodiment having the above-described structure, since the 2DEG exclusion regions 260B are formed under regions widthwise adjacent to the end portions 212A of the source electrodes 212, concentration of electron flows from the end portions 212A of the source electrodes 212 toward the ends 211A of the drain electrodes 211 can be suppressed so that the dynamic withstand voltage can be improved even if the lengthwise one-side end portions 212A of the source electrodes 212 are protruded lengthwise outer than the lengthwise one-side ends 211A of the drain electrodes 211.

Also according to the third embodiment, by virtue of the formation of the 2DEG exclusion regions 260A extending widthwise between the lengthwise extending portions 230B of the gate electrode 230, which are lengthwise outwardly opposed to the one-side ends 211A of the drain electrodes 211, and the source-electrode connecting portion 214 so as to reach the end portions 212A of the source electrodes 212, it is considered, the concentration of electron flows toward the ends 211A of the drain electrodes 211 can be further suppressed, so that the dynamic withstand voltage can be improved.

More specifically, in this embodiment, the static OFF withstand voltage was 600 V and the dynamic withstand voltage, which is the dynamic OFF withstand voltage, was 300 V. Therefore, according to this embodiment, the dynamic withstand voltage showed an improvement of 100% or more as compared with the prior art example.

In addition, in the above third embodiment, 2DEG exclusion regions may also be formed under regions lengthwise adjacent to the lengthwise ends 211A of the drain electrodes 211 between the ends 211A and the connecting portion 230C of the gate electrode 230. In this case, the concentration of electron flows toward the end portions of the drain electrodes 211 can be even more suppressed during the dynamic withstand voltage test, so that improvement in the dynamic OFF withstand voltage can be achieved.

In the first to third embodiments, the finger-like drain electrodes 11, 91, 211 are provided three in number, and the finger-like source electrodes 12, 92, 212 are provided four in number. However, it is also allowable that the finger-like drain electrodes are provided two in number and the finger-like source electrodes are provided three in number, where the drain electrodes and the source electrodes are alternately placed in a widthwise direction intersecting the lengthwise direction. Further, it is also allowable that the finger-like drain electrode is provided one in number while finger-like source electrodes 62 are provided two in number, or that the finger-like drain electrodes are provided three or more in number while the finger-like source electrodes are provided four or more in number, where the drain electrodes and the source electrodes are alternately placed in the widthwise direction.

Also in the first to third embodiments, the substrate 1, 81, 201 is provided as a Si substrate. However, without being limited to a Si substrate, it is also allowable to use a sapphire substrate or a SiC substrate, where a nitride semiconductor layer may be grown on the sapphire substrate or Si substrate, or Ga-based semiconductor layers may be grown on a substrate made of Ga-based semiconductor, e.g., an AlGaN layer may be grown on a GaN substrate. Also, as required, buffer layers may be formed between the substrate and the individual layers. Further, a hetero-improvement layer made from AlN may also be formed between the undoped GaN layer 2, 82, 202 and the undoped AlGaN layer 3, 83, 203. A GaN cap layer may also be formed on the undoped AlGaN layer 3, 83, 203. Moreover, in the first to third embodiments, recesses reaching the undoped GaN layer are formed, and drain electrodes and source electrodes are formed as ohmic electrodes in the recesses. However, without forming the recesses, drain electrodes and source electrodes may be formed on an undoped AlGaN layer formed on the undoped GaN layer, where the undoped AlGaN layer is made thinner in layer thickness so that the drain electrodes and the source electrodes become ohmic electrodes.

Also in the first to third embodiments, the gate electrode 33, 93, 230 is formed from TiN, but may be formed from WN. Also, the gate electrode may be formed from Ti/Au or Ni/Au. Also in the first to third embodiments, the drain electrodes 11, 91, 211 and the source electrodes 12, 92, 212 are provided as Ti/Al/TiN electrodes as an example, but may be provided as Ti/Al electrodes or Hf/Al electrodes or Ti/AlCu/TiN electrodes. Further, the drain electrodes and the source electrodes may be multilayered ones in which Ni/Au is stacked on Ti/Al or Hf/Al, or multilayered ones in which Pt/Au is stacked on Ti/Al or Hf/Al, or multilayered ones in which Au is stacked on Ti/Al or Hf/Al.

Also in the first to third embodiments, the protective film is formed from SiN, but may be formed from SIO₂, Al₂O₃ or the like and may also be a multilayered film in which a SiO₂ film is stacked on a SiN film. Also, the GaN-based multilayered body in the field-effect transistor of the invention may be one including a GaN-based semiconductor layer represented by AlₓIn_{y}Ga_{1-x-y}N (X≧0, Y≧0, 0≦x+Y≦1). That is, the GaN-based multilayered body may be one including AlGaN, GaN, InGaN or the like.

Further, although normally-ON type HFETs have been described above, yet normally-OFF type HFETs may be used well enough to produce the same effects. Still more, although the Schottky gate has been employed in the above description, yet the insulated gate structure may also be employed similarly.

Although specific embodiments of the present invention have been described hereinabove, yet the invention is not limited to the above embodiments and may be carried out as they are changed and modified in various ways within the scope of the invention.

### REFERENCE SIGNS LIST

1, 81, 201 Si substrate
2, 82, 202 undoped GaN layer
3, 83, 203 undoped AlGaN layer
5, 85, 205 GaN-based multilayered body
6, 86, 206 2DEG (2-Dimensional Electron Gas)
7, 87, 207 SiN projective film
8, 88, 208 interlayer insulating film
11, 91, 211 drain electrode
11A, 11B, 91A, 91B, 211A end
12, 92, 212 source electrode
12A, 12B, 92A, 92B end
31, 51, 111, 111A, 151, 260A, 260B 2DEG exclusion region
33, 38, 93, 230 gate electrode
33A, 93A, 230E lengthwise extending portion
33B, 38B, 230A connecting portion
35, 108, 109, 250A, 250B recess
93B, 93C curved portion
15, 95 drain interconnection
17, 18, 97, 98 through hole
20, 103 source interconnection
212A end portion
213 drain-electrode connecting portion
214 source-electrode connecting portion

1. A heterojunction field-effect transistor comprising:
a GaN-based multilayered body (5, 85, 205) having a heterojunction;
a finger-like drain electrode (11, 91, 211) formed on the GaN-based multilayered body (5, 85, 205);
a finger-like source electrode (12, 92, 212) formed on the GaN-based multilayered body (5, 85, 205) so as to neighbor the drain electrode (11, 91, 211) in a direction intersecting a lengthwise direction in which the drain electrode (11, 91, 211) extends, the source electrode (12, 92, 212) also extending in the lengthwise direction; and
a gate electrode (33, 38, 93, 230) formed between the drain electrode (11, 91, 211) and the source electrode (12, 92, 212) as viewed in a plan view of the heterojunction field-effect transistor, wherein
a 2DEG (2-Dimensional Electron Gas) exclusion region (31, 51, 111, 111A, 151, 152, 260A, 260B) in which no 2DEG is present is formed in at least either one of:
a portion of the GaN-based multilayered body (5, 85, 205) under a region which is positioned lengthwise outer than an imaginary line extended from a lengthwise end (11A, 11B, 91A, 91B, 211A) of the drain electrode (11, 91, 211) in a widthwise direction orthogonal to the lengthwise direction and which is adjacent to the source electrode (12, 92, 212); and
a portion of the GaN-based multilayered body (5, 85, 205) under a region which is lengthwise outwardly adjacent to the lengthwise end (11A, 11B, 91A, 91B, 211A) of the drain electrode (11, 91, 211).

2. The heterojunction field-effect transistor as claimed in claim 1, wherein
the 2DEG exclusion region (31, 51, 111, 111A, 151, 152) in which no 2DEG is present is formed at least in the GaN-based multilayered body (5, 85) under a region which is lengthwise outwardly adjacent to a lengthwise end of the source electrode (12, 92).

3. The heterojunction field-effect transistor as claimed in claim 1, wherein
a lengthwise length of the source electrode (12, 92) is equal to a lengthwise length of the drain electrode (11, 91), or the lengthwise length of the source electrode (12, 92) is shorter than the lengthwise length of the drain electrode (11, 91), an imaginary line extended from a lengthwise first end (11A, 91A) of the source electrode (12, 92) in the widthwise direction orthogonal to the lengthwise direction is in contact with the drain electrode (11, 91) or intersects the drain electrode (11, 91), and
an imaginary line extended from a second end (11B, 91B) of the source electrode (12, 92) in the widthwise direction orthogonal to the lengthwise direction is in contact with the drain electrode (11, 91) or intersects the drain electrode (11, 91).

4. The heterojunction field-effect transistor as claimed in claim 1, wherein
the gate electrode (33, 38, 93, 230), as seen in the plan view, extends in the lengthwise direction between the finger-like drain electrode (11, 91, 211) and the finger-like source electrode (12, 92, 212) and moreover extends so as to surround a lengthwise end portion (11A, 11B, 91A, 91B, 211A) of the drain electrode (11, 91, 211).

5. The heterojunction field-effect transistor as claimed in claim 4, wherein
the 2DEG exclusion region (31) in which no 2DEG is present is formed in the GaN-based multilayered body (5) under a region surrounded by the imaginary line extended from the lengthwise end (11A, 11B) of the drain electrode (11) in the widthwise direction orthogonal to the lengthwise direction and the gate electrode (33, 38).

6. The heterojunction field-effect transistor as claimed in claim 4, wherein
the 2DEG (86) due to the heterojunction is left remaining in the GaN-based multilayered body (85) under a region surrounded by the imaginary line extended from the lengthwise end (91A, 91B) of the drain electrode (91) in the widthwise direction orthogonal to the lengthwise direction and the gate electrode (93).

7. The heterojunction field-effect transistor as claimed in claim 1, wherein
a lengthwise one-side end portion (212A) of the finger-like source electrode (212) is positioned lengthwise outer than an imaginary line extended from a lengthwise one-side end (211A) of the finger-like drain electrode (211) in the widthwise direction orthogonal to the lengthwise direction, and
the 2DEG exclusion region (260A, 260B) is formed in the GaN-based multilayered body (205) under a region which is positioned lengthwise outer than an imaginary line extended from the lengthwise one-side end (211A) of the drain electrode (211) in the widthwise direction orthogonal to the lengthwise direction and which is widthwise adjacent to the end portion (212A) of the source electrode (212).

8. The heterojunction field-effect transistor as claimed in claim 2, wherein
a lengthwise length of the source electrode (12, 92) is equal to a lengthwise length of the drain electrode (11, 91), or the lengthwise length of the source electrode (12, 92) is shorter than the lengthwise length of the drain electrode (11, 91), an imaginary line extended from a lengthwise first end (11A, 91A) of the source electrode (12, 92) in the widthwise direction orthogonal to the lengthwise direction is in contact with the drain electrode (11, 91) or intersects the drain electrode (11, 91), and
an imaginary line extended from a second end (11B, 91B) of the source electrode (12, 92) in the widthwise direction orthogonal to the lengthwise direction is in contact with the drain electrode (11, 91) or intersects the drain electrode (11, 91).

9. The heterojunction field-effect transistor as claimed in claim 2, wherein
the gate electrode (33, 38, 93, 230), as seen in the plan view, extends in the lengthwise direction between the finger-like drain electrode (11, 91, 211) and the finger-like source electrode (12, 92, 212) and moreover extends so as to surround a lengthwise end portion (11A, 11B, 91A, 91B, 211A) of the drain electrode (11, 91, 211).

10. The heterojunction field-effect transistor as claimed in claim 3, wherein
the gate electrode (33, 38, 93, 230), as seen in the plan view, extends in the lengthwise direction between the finger-like drain electrode (11, 91, 211) and the finger-like source electrode (12, 92, 212) and moreover extends so as to surround a lengthwise end portion (11A, 11B, 91A, 91B, 211A) of the drain electrode (11, 91, 211).

11. The heterojunction field-effect transistor as claimed in claim 4, wherein
a lengthwise one-side end portion (212A) of the finger-like source electrode (212) is positioned lengthwise outer than an imaginary line extended from a lengthwise one-side end (211A) of the finger-like drain electrode (211) in the widthwise direction orthogonal to the lengthwise direction, and
the 2DEG exclusion region (260A, 260B) is formed in the GaN-based multilayered body (205) under a region which is positioned lengthwise outer than an imaginary line extended from the lengthwise one-side end (211A) of the drain electrode (211) in the widthwise direction orthogonal to the lengthwise direction and which is widthwise adjacent to the end portion (212A) of the source electrode (212).

12. The heterojunction field-effect transistor as claimed in claim 5, wherein
a lengthwise one-side end portion (212A) of the finger-like source electrode (212) is positioned lengthwise outer than an imaginary line extended from a lengthwise one-side end (211A) of the finger-like drain electrode (211) in the widthwise direction orthogonal to the lengthwise direction, and
the 2DEG exclusion region (260A, 260B) is formed in the GaN-based multilayered body (205) under a region which is positioned lengthwise outer than an imaginary line extended from the lengthwise one-side end (211A) of the drain electrode (211) in the widthwise direction orthogonal to the lengthwise direction and which is widthwise adjacent to the end portion (212A) of the source electrode (212).

13. The heterojunction field-effect transistor as claimed in claim 6, wherein
a lengthwise one-side end portion (212A) of the finger-like source electrode (212) is positioned lengthwise outer than an imaginary line extended from a lengthwise one-side end (211A) of the finger-like drain electrode (211) in the widthwise direction orthogonal to the lengthwise direction, and
the 2DEG exclusion region (260A, 260B) is formed in the GaN-based multilayered body (205) under a region which is positioned lengthwise outer than an imaginary line extended from the lengthwise one-side end (211A) of the drain electrode (211) in the widthwise direction orthogonal to the lengthwise direction and which is widthwise adjacent to the end portion (212A) of the source electrode (212).
